(19) United States
(12) Patent Application Publication
(10) Pub. No.: US 2008/0153239 A1
(43) Pub. Date: Jun. 26, 2008

(54) Semiconductor process for butting contact and semiconductor circuit device having a butting contact

(75) Inventors: Hung-Der Su, Hsinchu (TW); Ching-Yao Yang, Changhua City (TW); Chien-Ling Chan, Hsinchu (TW)

Correspondence Address: Tung & Associates, 838 W. Long Lake Road, Suite 120, Bloomfield Hills, MI, 48302, US

(73) Assignee: Richtek Technology Corporation

(21) Appl. No.: 11/805,979

(22) Filed: May 25, 2007

(30) Foreign Application Priority Data
Dec. 20, 2006 (TW) 95147874

(51) Int. Cl. H01L 21/336; G03F 1/00

(52) U.S. Cl. 438/302; 430/5; 257/E21.409

(57) ABSTRACT

According to the present invention, a semiconductor process for butting contact comprises: providing a substrate on which are formed two adjacent transistor gates; implanting a full area between the two adjacent transistor gates by a tilt angle, to form a lightly doped region of a first conductivity type; forming a heavily doped region of the first conductivity type and a heavily doped region of a second conductivity type in the area between the two adjacent transistor gates, in which the heavily doped region of the second conductivity type overrides the lightly doped region of the first conductivity type, and divides the heavily doped region of the first conductivity type into two areas; depositing a dielectric layer; and forming a butting contact in the dielectric layer which concurrently contacts the two divided heavily doped regions of the first conductivity type.

### FIELD OF INVENTION

The present invention relates to a semiconductor process for butting contact and a semiconductor circuit device having a butting contact.

### BACKGROUND OF THE INVENTION

In a semiconductor circuit device, if a source or drain region of a field effect transistor (FET) is to be connected with a source or drain region of a neighboring FET, and both regions are to be connected to a first-level interconnection layer, the two FETs can be connected to the first-level interconnection layer by one contact, to save circuit area. Such structure is called “butting contact”. An example of such butting contact for N-type MOSFETs is shown in FIG. 1, in which the reference number 10 denotes the butting contact. As shown in the figure, for better electric performance, an N-type lightly doped region (NLDD) is provided above each N+ region, and a P-type lightly doped region (PLDD) is provided above the P+ region beneath the butting contact.

In order to provide a better doping contour for the source or drain region of the FET, a tilt-angle implant step is often used to implant impurities beneath the gate of the FET. An example of such tilt-angle implant is the so-called “pocket implant”.

FIGS. 2A-2F are schematic cross-sectional diagrams showing the steps of a conventional process for making a butting contact between NMOSFETs, which include a tilt-angle implant step. First, as shown in FIG. 2A, active regions are defined in a wafer substrate, and transistor gates 21 are formed. Next, a photoresist pattern 22 for N-type lighted doped regions (referred to hereinafter as “NLDD”) is formed on the wafer substrate (FIG. 2B). A tilt-angle implant step 23 follows to form the NLDDs (FIG. 2C). Next, after a photoresist patterning step (not shown), an implant step for P-type lightly doped region (referred to hereinafter as “PLDD”) is taken to form PLDDs, and spacers 26 are formed (FIG. 2D). A photolithography step, an implant step, another photolithography step and another implant step follow, to form heavily doped regions N+ 27 and P+ 28 (FIG. 2E). Last, as shown in FIG. 2F, after a dielectric layer 29 is deposited and contact holes are opened (by photolithography and etch), a conductive material is filled into the holes to form contacts. The contact 10 concurrently contacts two neighboring FETs, and therefore it is called “butting contact”.

The process shown in FIGS. 2A-2F has the following drawback. Referring to FIG. 2C, in the area where a butting contact is required, the two neighboring FETs must be very close to each other; otherwise it is meaningless to form a butting contact. However, because the source or drain regions of the two FETs are very close to each other, the photoresist above the butting contact area will block the tilt-angle implant 23, making it difficult to implant the impurities beneath the gates of the FETs, or even the areas besides the gates of the FETs (the areas beneath the spacers 26 to be formed later). Due to the narrow lateral space, and also due to the difference between the thickness of the photoresist and the height of the gate, it is even worse than what is shown in the figure, in a real case.

### SUMMARY OF THE INVENTION

In view of the foregoing drawback, it is therefore an objective of the present invention to provide a semiconductor process for butting contact, to solve the problem.

It is a second objective of the present invention to provide a semiconductor circuit device having a butting contact.

It is a third objective of the present invention to provide a mask set for making a butting contact.

In accordance with the foregoing and other objectives of the present invention, and as disclosed by one embodiment of the present invention, a semiconductor process for butting contact comprises: providing a substrate on which are formed two adjacent transistor gates; implanting a full area between the two adjacent transistor gates by a tilt angle, to form a lightly doped region of a first conductivity type; forming a heavily doped region of the first conductivity type and a heavily doped region of a second conductivity type in the area between the two adjacent transistor gates, in which the heavily doped region of the second conductivity type overrides the lightly doped region of the first conductivity type, and divides the heavily doped region of the first conductivity type into two areas; depositing a dielectric layer; and forming a butting contact in the dielectric layer which concurrently contacts the two divided heavily doped regions of the first conductivity type.

The above-mentioned process may further comprise: forming a lightly doped region of the second conductivity type in a part of the heavily doped region of the first conductivity type.

The first conductivity type can be either N-type or P-type.

According to another aspect of the present invention, a semiconductor circuit device having a butting contact is disclosed, which comprises: at least a first and a second adjacent transistors, a source or drain of the first transistor being nearby a source or drain of the second transistor, and both of the source or drain of the first transistor and the source or drain of the second transistor are of a first conductivity type; a butting contact concurrently contacting both of the source or drain of the first transistor and the source or drain of the second transistor; a lightly doped region of a first conductivity type beneath the butting contact, and a heavily doped region of a second conductivity type beneath the butting contact, which at least partially superimposes the lightly doped region of a first conductivity type.

According to yet another aspect of the present invention, a mask set for making a butting contact, is disclosed, which comprises: a first mask for implantation of impurities of a first conductivity type to form a lightly doped region, the mask fully opening an area for the butting contact; a second mask for implantation of impurities of a first conductivity type to form a heavily doped region, the mask partially opening the area for the butting contact; and a third mask for implantation of impurities of a second conductivity type, the mask partially opening the area for the butting contact.

The third mask maybe used as the mask for implantation to form a lightly doped region of a second conductivity type, and also the mask for implantation to form a heavily doped region of a second conductivity type.

It is to be understood that both the foregoing general description and the following detailed description are provided as examples, for illustration rather than limiting the scope of the invention.

### BRIEF DESCRIPTION OF THE DRAWINGS

These and other features, aspects, and advantages of the present invention will become better understood with regard to the following description, appended claims, and accompanying drawings where:

FIG. 1 is a schematic cross-sectional diagram showing a typical structure of a butting contact;

FIGS. 2A-2F are schematic cross-sectional diagrams showing the steps of a conventional process for butting contact, which include a tilt-angle implant step; and

FIGS. 3A-3G are schematic cross-sectional diagrams showing the process steps according to a preferred embodiment of the present invention.

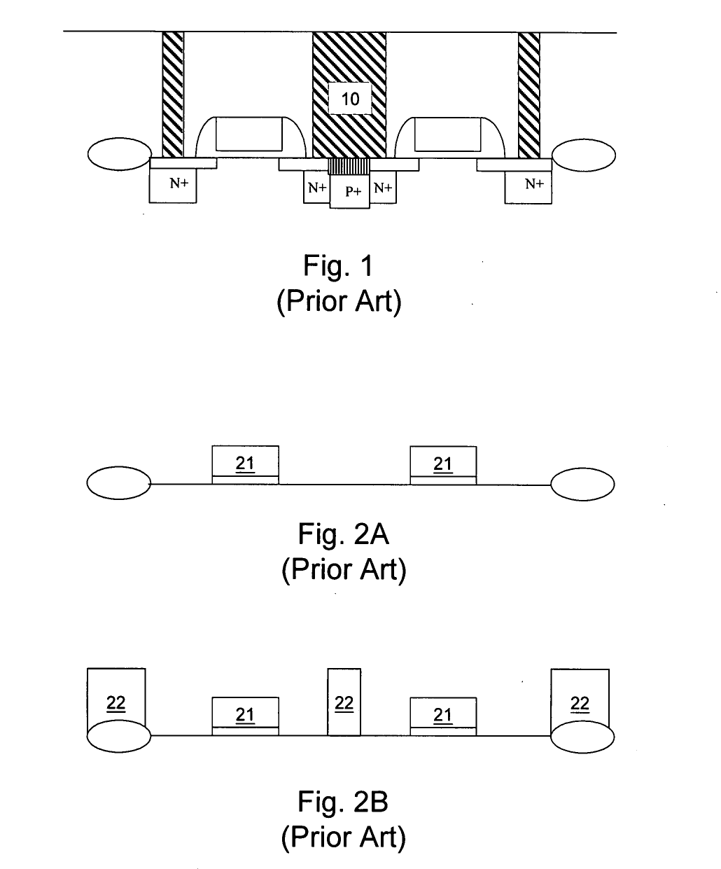

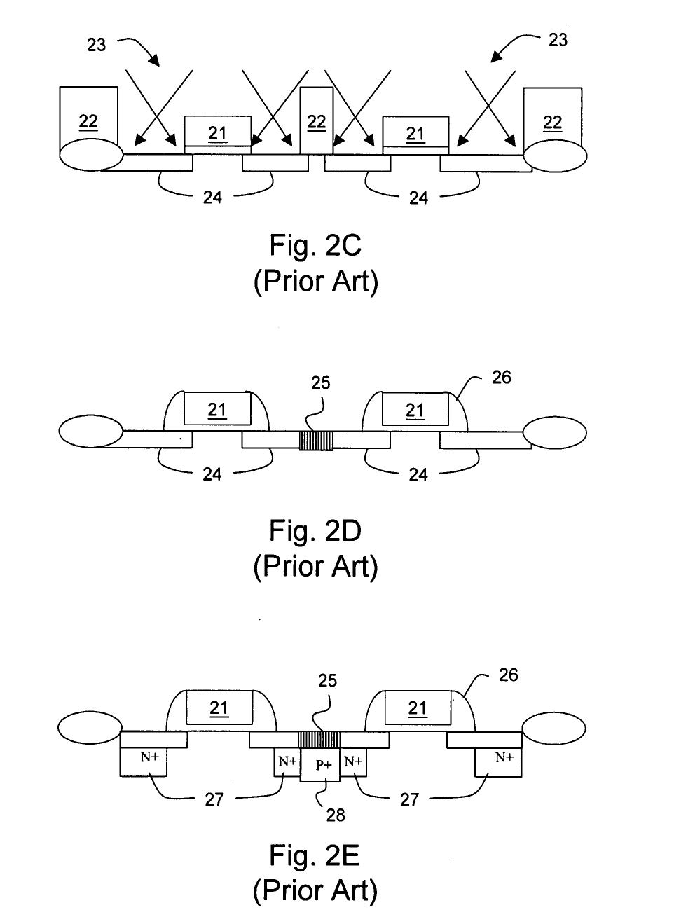

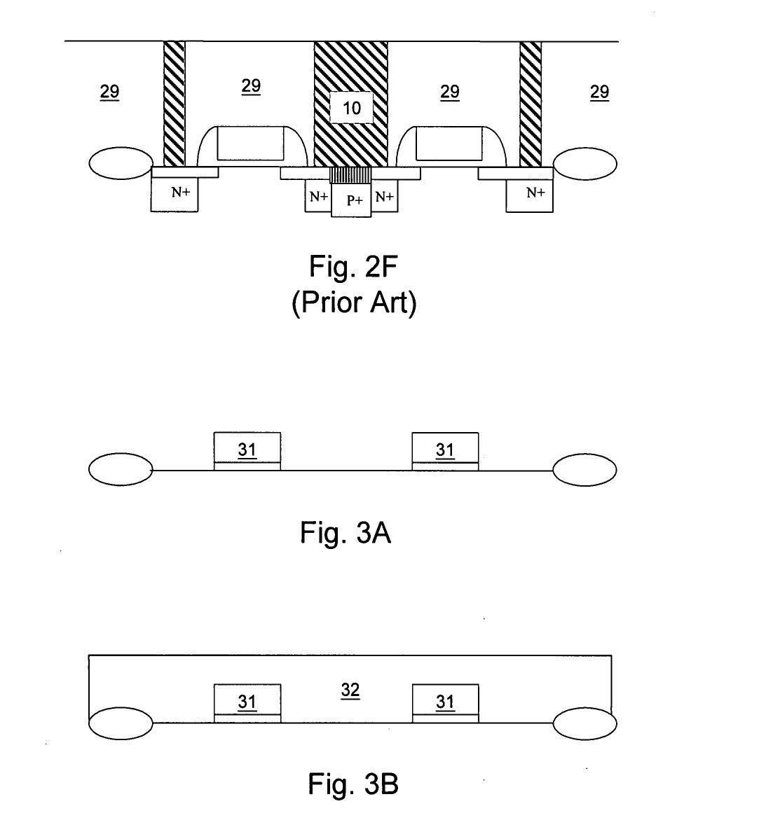

### DETAILED DESCRIPTION OF THE EMBODIMENTS

The drawings as referred to throughout the description of the present invention are for illustration only, but not drawn according to actual scale.

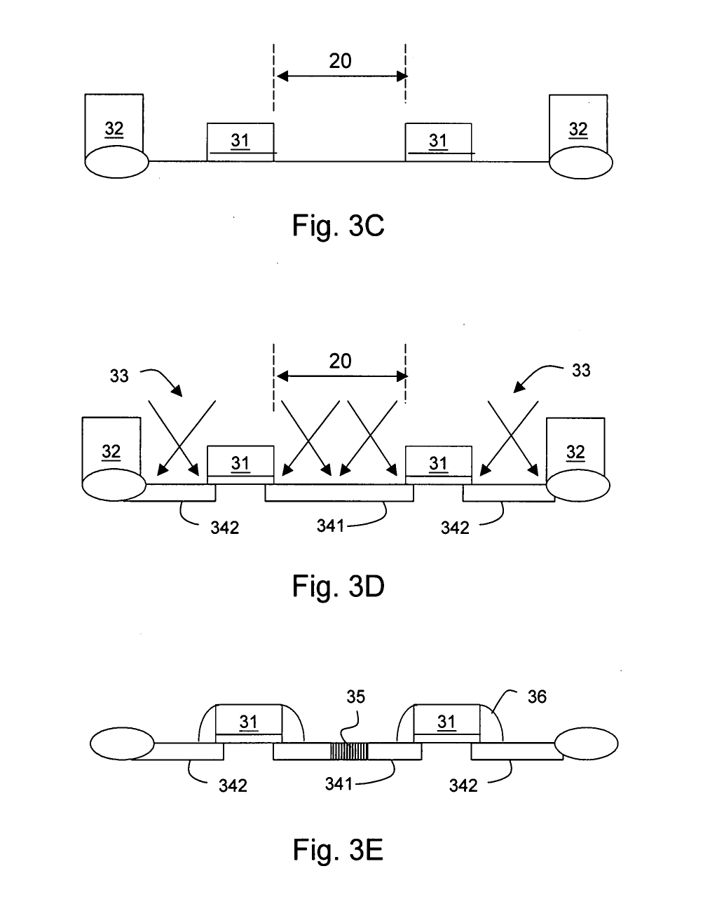

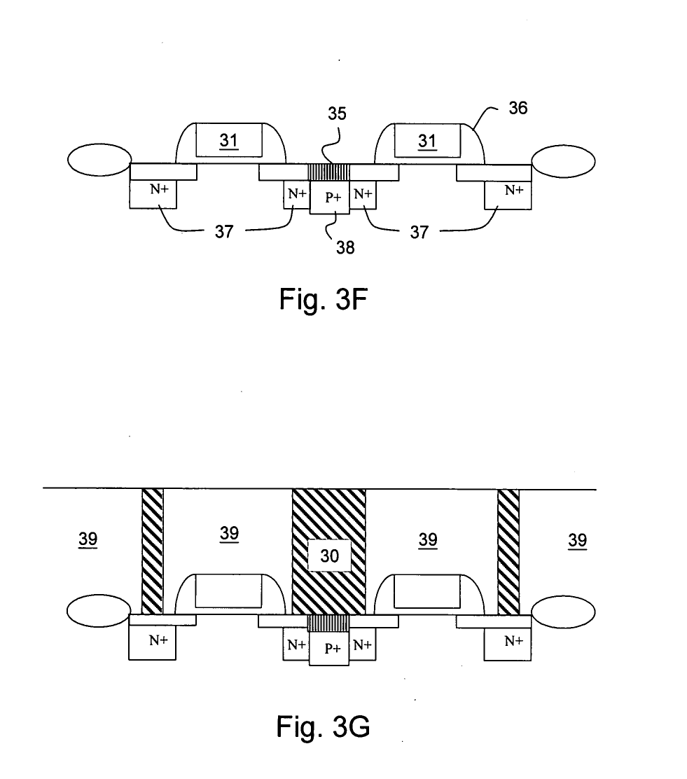

FIGS. 3A-3G are schematic cross-sectional diagrams showing the process steps for making a butting contact according to a preferred embodiment of the present invention. In the embodiment, the butting contact is formed between two NMOSFETs; one skilled in this art may readily apply the same spirit to PMOSFETs or other semiconductor devices. The steps of the process are as follows.

FIG. 3A: active regions are defined in a wafer substrate, and transistor gates 31 are formed.

FIG. 3B: a photoresist layer 32 is formed on the wafer substrate by spin coating or other methods.

FIG. 3C: a photolithography step is performed on the photoresist layer 32 according to an NLDD mask of the present invention (or a PLDD mask, if for PMOSFETs). In the pattern of the mask and the photolithography step, the area 20 between the FETs for butting contact is open; no photoresist is left there. The actual layout of the mask pattern should depend on the type of photoresist that is used (positive or negative photoresist) and the circuit layout design.

FIG. 3D: a tilt-angle implant step 33 is performed according to the photoresist pattern 32 formed in the previous step (FIG. 3C), to form the NLDDs 341 and 342. Note that because there is no photoresist in the area 20, the area 20 is subject to a blanket implant. The NLDD 341 connects two FETs; it is not divided.

FIG. 3E: after the photoresist layer 32 is removed, a PLDD mask is used to implant a PLDD 35 in the location where the butting contact is to be formed, between the two FETs (the photoresist coating, exposure and removal steps are omitted) In fact, it is not necessarily required to implant P-type lightly doped impurities in the area 35; the area 35 may be kept in the form shown in FIG. 3D, in the present step. However, it is required to implant heavily doped P+ impurities in the area 35 in the future, and it is more cost-effective if the pattern of the PLDD mask is the same as that of the P+ mask. Thus, for mask cost reason it is preferred to implant P-type lightly doped impurities in the area 35 here.

In FIG. 3E, spacers 36 are formed by spacer deposition and etch steps that are well-known to one skilled in this art. Note that the PLDD implant step and the spacer deposition and etch steps are interchangeable in sequence.

FIG. 3F: a photolithography step, an implant step, another photolithography step and another implant step follow, to form heavily doped regions N+ 37 and P+ 38. The sequence for forming the N+ regions and the P+ regions may be reversed, but usually the N+ implant is taken first. Note that according to the present invention, the N+ mask for forming the N+ heavily doped regions (P+ mask for forming the P+ heavily doped regions, if for PMOSFETs) is not the same as the NLDD mask for forming the N-type lightly doped regions (PLDD mask, if for PMOSFETs), because the patterns of the two mask are different in the area for forming the butting contact.

Although there are N-type impurities in the area of butting contact because of the step of FIG. 3D, the P+ heavily doped impurities override the effect of the lightly doped N-type impurities, without any side effect to damage the well pick up performance. Even if the PLDD implant of FIG. 3F does not implant any P-type impurity into this butting contact area, the well pick up performance can still function well by properly adjusting the dose of the P+ implant. And if the PLDD implant of FIG. 3F implants P-type impurities into this butting contact area, the well pickup performance can be more easily secured.

FIG. 3G: as shown in the figure, after a dielectric layer 39 is deposited and contact holes are opened (by photolithography and etch), a conductive material is filled into the holes to form contacts. The contact 30 is the butting contact because it concurrently contacts two neighboring FETs.

Although the present invention has been described in detail with reference to certain preferred embodiment thereof, the description is for illustrative purpose rather than limiting the scope of the invention. For example, in addition to the steps explicitly mentioned, other steps can be interchangeable. As another example, the photolithography step by means of a photoresist is described in the embodiment because it is the currently mature technology to pattern a layer; however, the present invention does not exclude other patterning methods such as E-beam lithography or immersion lithography. One skilled in this art can readily think of any modifications and variations in light of the teaching by the present invention. In view of the foregoing, it is intended that the present invention cover all such modifications and variations, which should interpreted to fall within the scope of the following claims and their equivalents.

What is claimed is:

1. A semiconductor process for butting contact, comprising:
providing a substrate on which are formed two adjacent transistor gates;
implanting a full area between the two adjacent transistor gates by a tilt angle, to form a lightly doped region of a first conductivity type;
forming a heavily doped region of the first conductivity type and a heavily doped region of a second conductivity type in the area between the two adjacent transistor gates, in which the heavily doped region of the second conductivity type overrides the lightly doped region of the first conductivity type, and divides the heavily doped region of the first conductivity type into two areas;
depositing a dielectric layer; and
forming a butting contact in the dielectric layer which concurrently contacts the two divided heavily doped regions of the first conductivity type.

2. The semiconductor process of claim 1, further comprising: forming spacers at the sides of the transistor gates.

3. The semiconductor process of claim 1, further comprising: forming a lightly doped region of the second conductivity type in a part of the lightly doped region of the first conductivity type.

4. The semiconductor process of claim 3, wherein the pattern of the lightly doped region of the second conductivity type is the same as the pattern of the heavily doped region of the second conductivity type.

5. The semiconductor process of claim 1, wherein the pattern of the lightly doped region of the first conductivity type is not the same as the pattern of the heavily doped region of the first conductivity type.

6. A semiconductor circuit device having a butting contact, comprising:
at least a first and a second adjacent transistors, a source or drain of the first transistor being nearby a source or drain of the second transistor, and both of the source or drain of the first transistor and the source or drain of the second transistor are of a first conductivity type;
a butting contact concurrently contacting both of the source or drain of the first transistor and the source or drain of the second transistor;
a lightly doped region of a first conductivity type beneath the butting contact, and
a heavily doped region of a second conductivity type beneath the butting contact, which at least partially superimposes the lightly doped region of a first conductivity type.

7. The semiconductor circuit device of claim 6, further comprising a lightly doped region of the second conductivity type beneath the butting contact.

8. A mask set for making a butting contact, comprising:
a first mask for implantation of impurities of a first conductivity type to form a lightly doped region, the mask fully opening an area for the butting contact;
a second mask for implantation of impurities of a first conductivity type to form a heavily doped region, the mask partially opening the area for the butting contact; and
a third mask for implantation of impurities of a second conductivity type, the mask partially opening the area for the butting contact.

9. The mask set of claim 8, wherein the third mask is for implantation of impurities of a second conductivity type to form a heavily doped region.

10. The mask set of claim 8, wherein the third mask is for implantation of impurities of a second conductivity type to form a heavily doped region, and also for implantation of impurities of a second conductivity type to form a lightly doped region.

11. The mask set of claim 9, further comprising a fourth mask for implantation of impurities of a second conductivity type to form a lightly doped region.
